(19) United States
(12) Patent Application Publication
(10) Pub. No.: US 2023/0290730 A1
(43) Pub. Date: Sep. 14, 2023

(54) PACKAGE DEVICE AND MANUFACTURING METHOD THEREOF

(71) Applicant: POWERTECH TECHNOLOGY INC., Hsinchu County (TW)

(72) Inventors: Shang-Yu Chang Chien, HSINCHU COUNTY (TW); Nan-Chun Lin, HSINCHU COUNTY (TW); Hung-Hsin Hsu, HSINCHU COUNTY (TW)

(73) Assignee: POWERTECH TECHNOLOGY INC., HSINCHU COUNTY (TW)

(21) Appl. No.: 18/078,055

(22) Filed: Dec. 8, 2022

(30) Foreign Application Priority Data
Mar. 9, 2022 (TW) 111108550

(51) Int. Cl. H01L 23/538; H01L 23/31; H01L 21/48; H01L 21/56

(52) U.S. Cl. CPC H01L 23/5381; H01L 23/5383; H01L 23/3128; H01L 21/4857; H01L 21/56; H01L 21/568; H01L 2224/16227; H01L 24/16

(57) ABSTRACT

A package device and a manufacturing method thereof are provided. The package device includes a substrate, a plurality of conductive pillars, at least one bridge chip, a photosensitive encapsulation layer, a redistribution layer, and at least two active chips. The conductive pillars and the bridge chip are disposed on the substrate. The photosensitive encapsulation layer surrounds the bridge chip and the conductive pillars, in which a distance between a top surface of the bridge chip and a top surface of the photosensitive encapsulation layer is less than a distance between a top surface of one of the conductive pillars and the top surface of the photosensitive encapsulation layer. The redistribution layer is disposed on the photosensitive encapsulation layer, the active chips are disposed on the redistribution layer, and the bridge chip is coupled between the active chips.

### BACKGROUND OF THE INVENTION

### 1. Field of the Invention

The present invention relates to a package device and a manufacturing method thereof and particularly to a package device with a bridge chip coupled to active chips and a manufacturing method thereof.

### 2. Description of the Prior Art

Recently, in order to integrate various functions to meet usage requirements, it has been developed to encapsulate multiple active chips in the same package device. However, as the active chips need to have more functions or higher computing power, efficiency requirements of an interconnection structure coupled between the active chips become higher. Accordingly, how to improve the interconnection efficiency between active chips and reduce manufacturing cost and process complexity of the package device is an important issue in this field.

### SUMMARY OF THE INVENTION

According to an embodiment of the present invention, a package device is provided and includes a substrate, a plurality of conductive pillars, at least one bridge chip, a photosensitive encapsulation layer, a redistribution layer, at least two active chips, and an encapsulant. The conductive pillars are disposed on the substrate side by side. The bridge chip is disposed on the substrate. The photosensitive encapsulation layer surrounds the bridge chip and the conductive pillars, in which a distance between a top surface of the bridge chip and a top surface of the photosensitive encapsulation layer is less than a distance between a top surface of one of the conductive pillars and the top surface of the photosensitive encapsulation layer. The redistribution layer is disposed on the photosensitive encapsulation layer. The active chips are disposed on the redistribution layer, and the bridge chip is coupled between the active chips. The encapsulant is disposed on the redistribution layer and surrounds the active chips.

According to another embodiment of the present invention, a manufacturing method of a package device is provided. First, a plurality of conductive pillars are formed on a carrier, and at least one bridge chip is disposed on the carrier. Then, a photosensitive encapsulation layer is formed on the conductive pillars and the bridge chip, in which the photosensitive encapsulation layer surrounds the bridge chip and the conductive pillars, and a distance between a top surface of the bridge chip and a top surface of the photosensitive encapsulation layer is less than a distance between a top surface of one of the conductive pillars and the top surface of the photosensitive encapsulation layer. Subsequently, a redistribution layer is formed on the photosensitive encapsulation layer. Then, at least two active chips are disposed on the redistribution layer, and an encapsulant is formed on the redistribution layer, in which the encapsulant surrounds the active chips. Thereafter, the carrier is removed.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 9 schematically illustrate a manufacturing method of a package device according to an embodiment of the present invention.

FIG. 10 schematically illustrates a cross-sectional view of a package device according to another embodiment of the present invention.

### DETAILED DESCRIPTION

The contents of the present disclosure will be described in detail with reference to specific embodiments and drawings. In order to make the contents clearer and easier to understand, the following drawings may be simplified schematic diagrams, and elements therein may not be drawn to scale. The numbers and sizes of the elements in the drawings are just illustrative and are not intended to limit the scope of the present disclosure.

Spatially relative terms, such as “above”, “on”, “beneath”, “below”, “under”, “left”, “right”, “before”, “front”, “after”, “behind” and the like, used in the following embodiments just refer to the directions in the drawings and are not intended to limit the present disclosure. It should be understood that the elements in the drawings may be disposed in any kind of formation known by one skilled in the related art to describe the elements in a certain way.

When one element or layer is referred to as “on” or “above” another element or another layer, it may be understood that the element or layer is “directly on” the another element or the another layer, or other element or other layer may be between them. On the contrary, when one element or layer is “directly on” another element or another layer, it may be understood that there is no element or layer between them.

When an element is referred to as being “electrically connected to” or “coupled to” another element, it may be understood that “other element maybe between the element and the another element and electrically connects them to each other”, or “there are no intervening elements present between the element and the another element, and the element and the another element are directly electrically connected to each other”. When an element is referred to as being “directly electrically connected to” or “directly coupled to” another element, there are no intervening elements present between the element and the another element, and the element and the another element are directly electrically connected to each other.

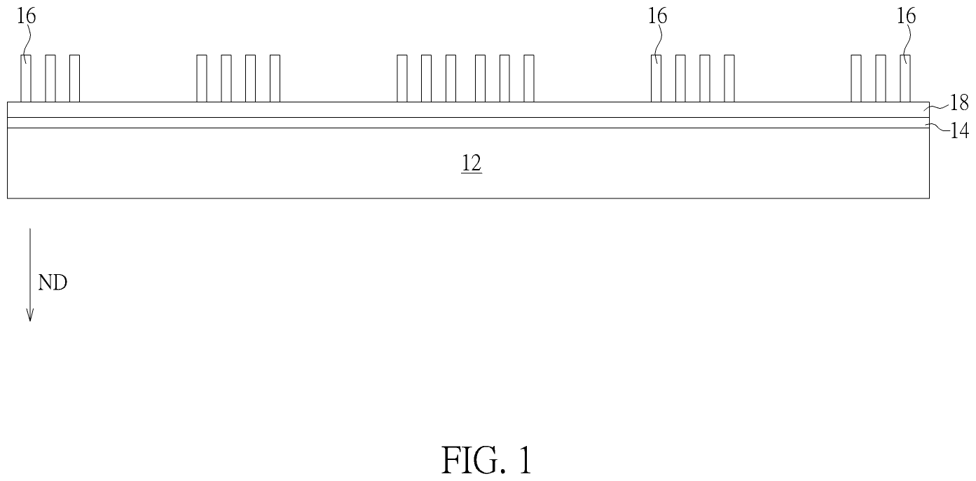

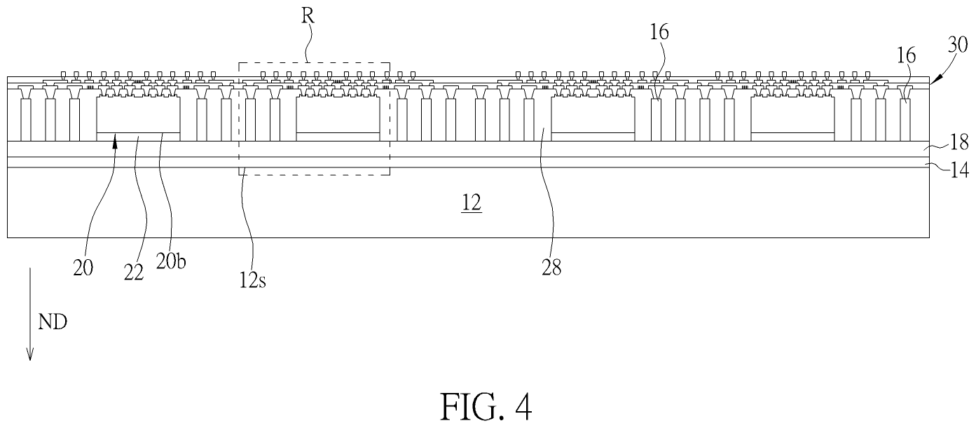

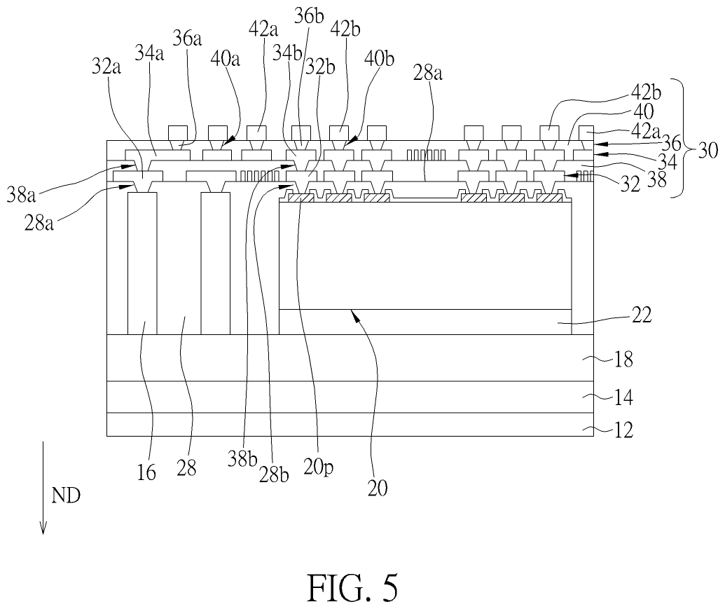

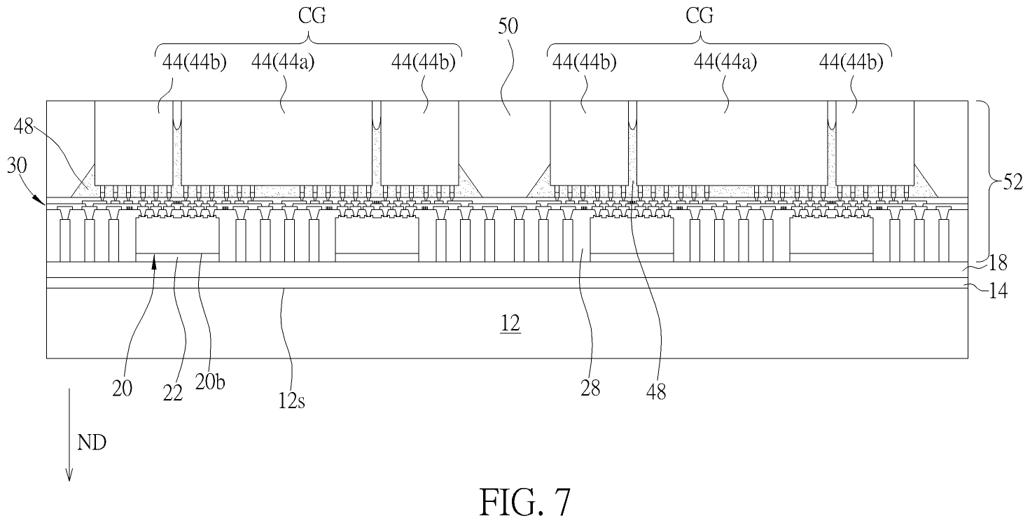

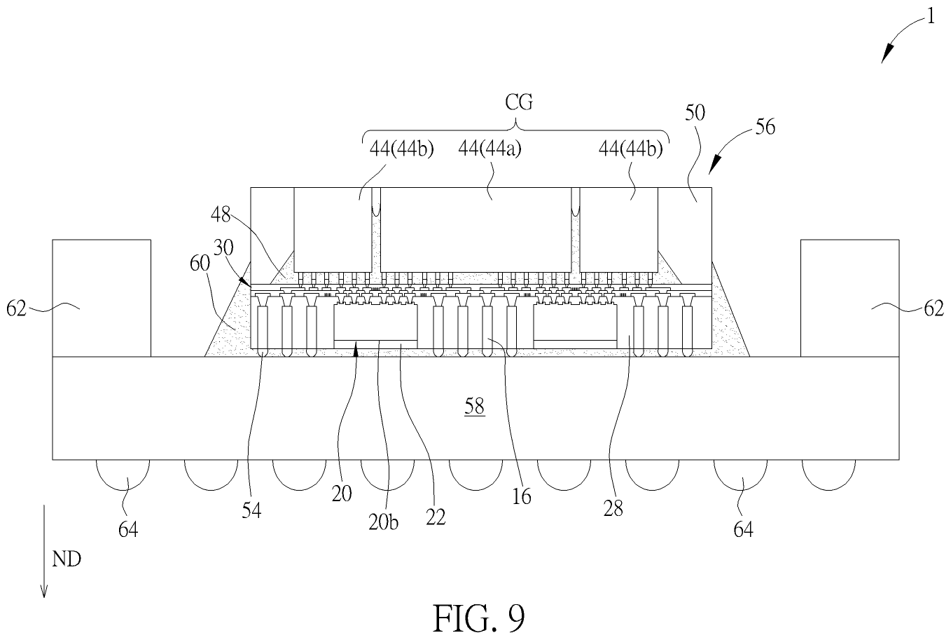

Please refer to FIG. 1 to FIG. 9. FIG. 1 to FIG. 9 schematically illustrate a manufacturing method of a package device according to an embodiment of the present invention, in which FIG. 5 is a schematic enlarged view of a region R in FIG. 4, and FIG. 9 schematically illustrates a cross-sectional view of the package device according to an embodiment of the present invention. The structures shown in FIG. 1 to FIG. 9 may be partial structures in different steps during manufacturing the package device, and some layers or elements may be omitted, but not limited thereto. As shown in FIG. 1, a carrier 12 is provided first, in which the carrier 12 may for example have a release layer 14 thereon. The carrier 12 may be used to carry films or elements formed thereon, and the carrier 12 may include for example glass, wafer substrate, metal, or other suitable supporting materials, but not limited thereto. The release layer 14 may be used to separate the carrier 12 from the elements formed thereon (e.g., a package structure 52 shown in FIG. 7) after subsequent steps are completed. The releasing method of the release layer 14 may include for example photo dissociation or other suitable methods. The release layer 14 may, for example, include polyethylene (PE), polyethylene terephthalate (PET), epoxy, oriented polypropylene (OPP) or other materials suitable material, but not limited thereto.

As shown in FIG. 1, a plurality of conductive pillars 16 disposed side by side may be formed on a carrier 12. The conductive pillars 16 may be formed by, for example, a deposition process combined with a photolithography process and an etching process, an electroplating process combined with an etching process, or other suitable processes. In the embodiment of FIG. 1, the conductive pillars 16 may be, for example, a single-layer structure or a multi-layer structure. The conductive pillars 16 may, for example, be formed of copper, but not limited thereto. In some embodiments, as shown in FIG. 1, a dielectric layer 18 may be optionally formed on the release layer 14 before the conductive pillars 16 are formed. In this case, the conductive pillars 16 may be formed on the dielectric layer 18, and as compared with being formed on the release layer 14, bonding between the conductive pillars 16 and the dielectric layer 18 may be better. Accordingly, the bonding between the conductive pillars 16 and the carrier 12 may be improved by the dielectric layer 18, and falling or toppling of the conductive pillars 16 from the carrier 12 may be reduced when the conductive pillars 16 is uprightly disposed on the carrier 12. The dielectric layer 18 may include, for example, polyimide (PI) or other suitable organic materials, but not limited thereto. In some embodiments, the dielectric layer 18 may have openings, and the conductive pillars 16 are partially formed in the openings, respectively, such that a part of each conductive pillar 16 is embedded in the dielectric layer 18 just like an anchor point, thereby reducing the toppling risk of the conductive pillars 16.

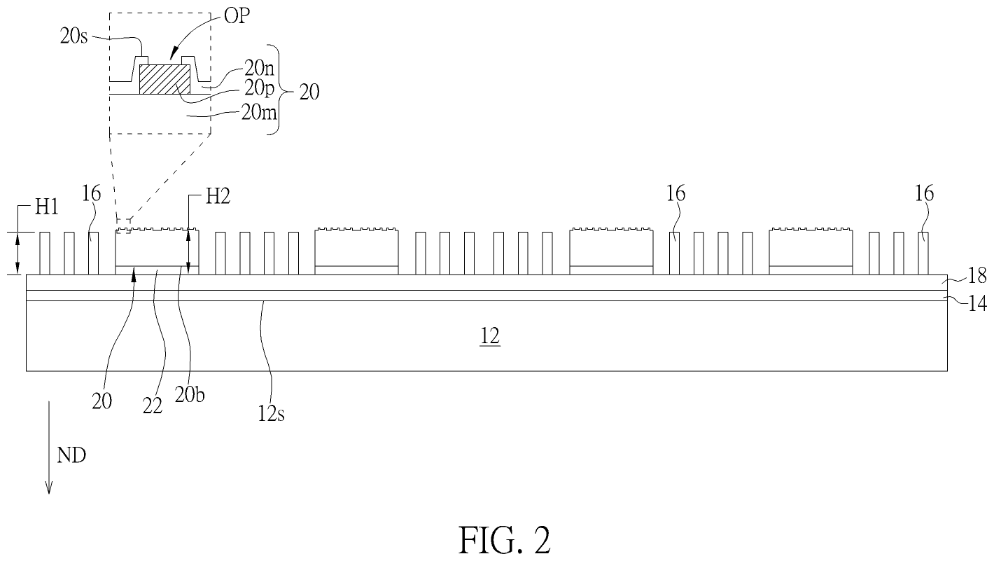

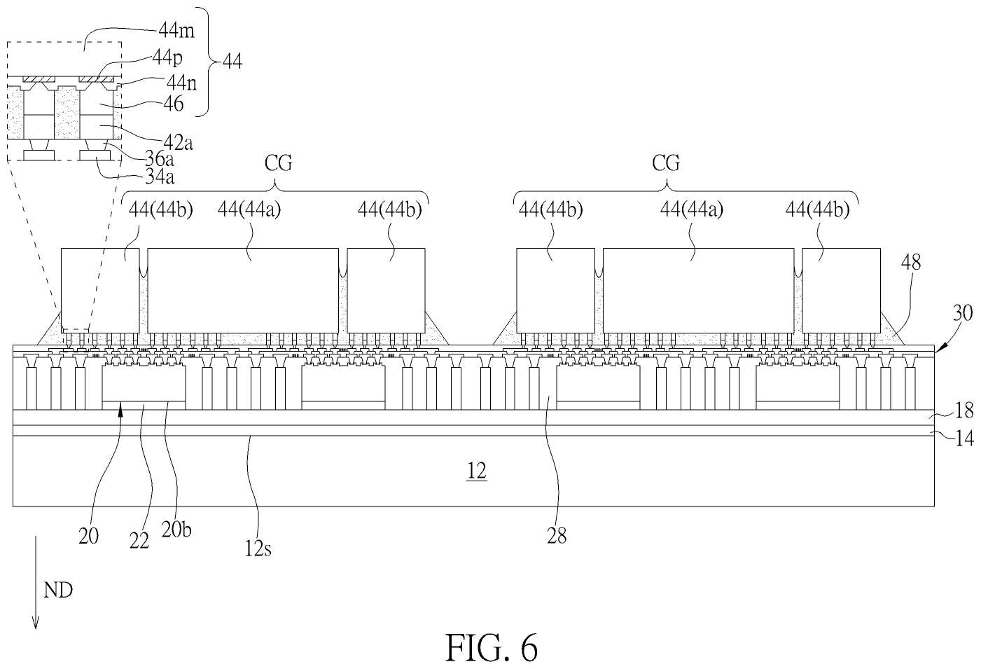

As shown in FIG. 2, after the conductive pillars 16 are formed, at least one bridge chip 20 may be disposed on the carrier 12 in a face-up manner. In other words, the bridge chip 20 may have a plurality of pads 20p facing upward, and a back surface 20b of the bridge chip 20 faces toward the carrier 12. For example, the step of disposing the bridge chip 20 may utilize an adhesive layer 22 to bond the bridge chip 20 to the release layer 14 (or the dielectric layer 18) through a die attach process. The adhesive layer 22 may include, for example, a die attach film (DAF), double-sided tape, or other suitable materials. The bridge chip 20 may include, for example, a plurality of traces for coupling active chips (e.g., active chips 44 shown in FIG. 6) formed in a subsequent process to each other. A trace pitch (e.g., fine pitch) in the bridge chip 20 may be, for example, 1 micrometer (μm) to 2 micrometers or on sub-micron scale, but not limited thereto. The number of bridge chip 20 shown in FIG. 2 may be plural, but not limited thereto. The number of bridge chip 20 may, for example, depend on the number of active chips in a chip group or the number of chip groups (e.g., chip groups CG shown in FIG. 6). In some embodiments, the bridge chip 20 may optionally further include a passive element, such as a resistor, a capacitor, an inductor, or other similar elements. In some embodiments, the bridge chip 20 may optionally further include an active element. In some embodiments, a thickness of the bridge chip 20 in a normal direction ND perpendicular to a top surface 12s of the carrier 12 may be, for example, about 10 micrometers to 100 micrometers or more. The chip mentioned herein may also be referred to as a die but is not limited thereto. The term “coupling” mentioned herein may also be referred to as “electrical connecting”, but not limited thereto.

In the embodiment of FIG. 2, the bridge chip 20 may have no bump on the pads 20p, so that the pads 20p may be exposed. Since it is not necessary to form bumps on the pads 20p of the bridge chip 20, the manufacturing cost may be reduced. For example, the bridge chip 20 may include a body portion 20m and an insulating layer 20n, in which the pads 20p may be disposed on the body portion 20m, and the insulating layer 20n may be disposed on the pads 20p and has openings OP respectively exposing corresponding pads 20p. The pads 20p may, for example, be aluminum pads, but not limited thereto.

In the embodiment shown in FIG. 2, a height H1 of one of the conductive pillars 16 may be, for example, lower than a height H2 of a top surface 20s of the bridge chip 20 opposite to the carrier 12 (e.g., the height H2 may be a distance between the top surface 20s and a surface of the dielectric layer 18 opposite to the release layer 14, or a sum of a thickness of the bridge chip 20 and a thickness of the adhesive layer 22). Accordingly, time and cost for manufacturing the conductive pillars 16 may be reduced. The top surface 20s of the bridge chip 20 may be formed by, for example, a top surface of the insulating layer 20n and top surfaces of the pads 20p shown in FIG. 2, but not limited thereto. In some embodiments, a distance between two adjacent conductive pillars 16 may be, for example, greater than a distance between two adjacent pads 20p, but not limited thereto.

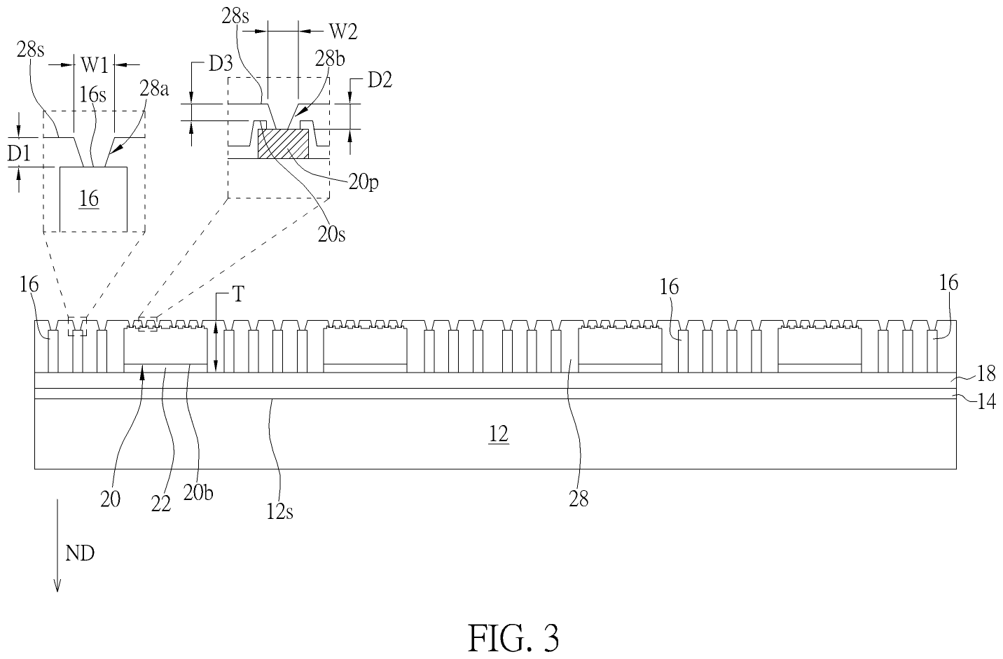

As shown in FIG. 3, a photosensitive encapsulation layer 28 may then be formed on the conductive pillars 16 and the bridge chip 20. For example, the photosensitive encapsulation layer 28 may be a dry film and is disposed on the conductive pillars 16 and the bridge chip 20 through a lamination process, in which the photosensitive encapsulation layer 28 may surround the conductive pillars 16 and the bridge chip 20. Then, a plurality of through holes 28a and a plurality of through holes 28b may be formed in the photosensitive encapsulation layer 28 through a photolithography process (i.e., an exposure process and a development process), in which the through holes 28a may expose the corresponding conductive pillars 16, and the through holes 28b may expose the corresponding pads 20p of the bridge chip 20. Since the photosensitive encapsulation layer 28 may extend to tops of the conductive pillars 16 and a top of the bridge chip 20, a distance D3 between the top surface 20s of the bridge chip 20 and a top surface 28s of the photosensitive encapsulation layer 28 opposite to the carrier 12 may be less than a distance D1 between a top surface 16s of one of the conductive pillars 16 and the top surface 28s of the photosensitive encapsulation layer 28.

It should be noted that, as compared with general photoresist materials, the photosensitive encapsulation layer 28 may have a greater thickness. Therefore, when the bridge chip 20 has a certain thickness (e.g., 10 μm to 100 μm), a thickness T of the photosensitive encapsulation layer 28 may still be greater than the height H1 of one of the conductive pillars 16 and the height H2 of the top surface 20s of the bridge chip 20, such that the top surface 28s of the photosensitive encapsulation layer 28 may be higher than the top surface 16s of one of the conductive pillars 16 and the top surface 20s of the bridge chip 20. In some embodiments, a depth of one of the through holes 28a (i.e., the distance D1 between the top surface 16s of one of the conductive pillars 16 and the top surface 28s of the photosensitive encapsulation layer 28) may be, for example, greater than a depth D2 of one of the through holes 28b (i.e., the distance between the top surface of one of the pads 20p and the top surface 28s of the photosensitive encapsulation layer 28). In some embodiments, a width W1 of one of the through holes 28a may be greater than a width W2 of one of the through holes 28b, for example. It should be noted that, since the through holes 28a exposing the conductive pillars 16 and the through holes 28b exposing the bridge chip 20 may be formed in the photosensitive encapsulation layer 28 through the photolithography process, the height H1 of one of the conductive pillars 16 may be designed to be less than the height H2 of the top surface 20s of the bridge chip 20, thereby reducing the manufacturing cost.

In addition, the photosensitive encapsulation layer 28 may not only have the photosensitive property, but also have filling and sealing properties, so that it may be disposed between the conductive pillars 16 and between the conductive pillars 16 and the bridge chip 20 to protect the conductive pillars 16 and the bridge chip 20. For example, the photosensitive encapsulation layer 28 may include a siloxane polymer (e.g., SINR produced from Shin-Etsu Chemical), or other suitable organic materials. It should be noted that the photosensitive encapsulation layer 28 may have a lower Young's modulus compared to conventional packaging materials (e.g., epoxy resin or molding material). In other words, the photosensitive encapsulation layer 28 does not cause significant stress on the conductive pillars 16, the bridge chip 20 and the carrier 12, so that warpage of the carrier 12 may be reduced in the subsequent process. Accordingly, affection to positions of the conductive pillars 16 and the pads 20p of the bridge chip 20 and relative positions of the subsequently formed elements (e.g., the redistribution layer 30 shown in FIG. 4 and FIG. 5) by the photosensitive encapsulation layer 28 maybe mitigated, and the process complexity of the package device may be reduced.

As shown in FIG. 4 and FIG. 5, a redistribution layer 30 may be formed on the photosensitive encapsulation layer 28, so that a part of the photosensitive encapsulation layer 28 may be disposed between the conductive pillars 16 and the redistribution layer 30 and between the bridge chip 20 and the redistribution layer 30. The redistribution layer 30 may include at least two conductive layers and at least one dielectric layer. In the embodiment of FIG. 5, the conductive layers of the redistribution layer 30 may include a conductive layer 32, a conductive layer 34 and a conductive layer 36, and the dielectric layer of the redistribution layer 30 may include a dielectric layer 38 and a dielectric layer 40 as an example, but not limited thereto. In some embodiments, the number of conductive layers and the number of dielectric layers maybe adjusted according to requirements.

In the embodiment of FIG. 5, the conductive layer 32 may be disposed on the photosensitive encapsulation layer 28 and include a plurality of traces 32a and a plurality of traces 32b, in which the traces 32a are respectively coupled to the corresponding conductive pillars 16 through the corresponding through holes 28a, and the traces 32b are respectively coupled to the corresponding pads 20p of the bridge chip 20 through the corresponding through holes 28b. For example, since the conductive pillars 16 and the pads 20p may be respectively exposed by the through holes 28a and 28b, one of the traces 32a of the conductive layer 32 may extend into the corresponding through hole 28a and directly contact the corresponding conductive pillar 16, and one of the traces 32b may extend into the corresponding through hole 28b and directly contact the corresponding pad 20p of the bridge chip 20. For this reason, there is no need to fabricate extra bumps on the pads 20p of the bridge chip 20 for bonding, thereby reducing the thickness of the bridge chip 20 and the thicknesses of the conductive pillars 16. The dielectric layer 38 may be disposed on the conductive layer 32 and have a plurality of through holes 38a and a plurality of through holes 38b respectively exposing parts of the corresponding traces 32a and the corresponding traces 32b. The conductive layer 34 maybe disposed on the dielectric layer 38 and include a plurality of traces 34a and a plurality of traces 34b. The traces 34a may be respectively coupled to the corresponding traces 32a through the corresponding through holes 38a, and the traces 34b may be respectively coupled to the corresponding traces 32b through the corresponding through holes 38b. The dielectric layer 40 may be disposed on the conductive layer 34 and the dielectric layer 38 and have a plurality of through holes 40a and a plurality of through holes 40b respectively exposing parts of the corresponding traces 34a and the corresponding traces 34b. The conductive layer 36 may include a plurality of blocks 36a and a plurality of blocks 36b respectively disposed in the through holes 40a and the through holes 40b. In some embodiments, the redistribution layer 30 may optionally further include conductive bumps 42a and conductive bumps 42b respectively disposed on the corresponding blocks 36a and the corresponding blocks 36b, so as to facilitate bonding of the redistribution layer 36 to an element (e.g., the active chip) formed in subsequent process. One of the conductive bumps 42a and the conductive bumps 42b may optionally be, for example, a multi-layered structure. The multi-layer structure may include, for example, copper, nickel, gold, other suitable materials, an alloy of at least two thereof, or a combination thereof, but not limited thereto. In some embodiments, the trace pitch (e.g., fine pitch) of the same conductive layer in the redistribution layer 30 may be, for example, 2 μm to 10 μm.

As shown in FIG. 6, at least two active chips 44 maybe disposed on the redistribution layer 30, so that the active chips 44 may be coupled to the bridge chip 20 through the redistribution layer 30, thereby being coupled to each other. In the embodiment shown in FIG. 6, the number of active chips 44 may be plural, and the active chips 44 may be divided into at least two chip groups CG respectively corresponding to the package devices to be formed (e.g., the package device shown in FIG. 9), but not limited thereto.

In the embodiment of FIG. 6, one of the active chips 44 may, for example, include a plurality of conductive bumps 46 to facilitate bonding with the redistribution layer 30, but not limited thereto. The conductive bumps 46 of the active chip 44 may be bonded to the conductive bumps 42a and the conductive bumps 42b of the redistribution layer 30, for example, in a face-down manner through a flip chip bonding process. Metal solders (not shown), such as tin alloy solders, may be disposed between the conductive bumps 46 and the conductive bumps 42a and between the conductive bumps 46 and the conductive bumps 42b, but not limited thereto. For example, one of the active chips 44 may further include a body portion 44m, a plurality of input/output pads 44p, and an insulating layer 44n, in which the input/output pads 44p may be disposed between the body portion 44m and the insulating layer 44n, and the insulating layer 44n has a plurality of openings exposing the corresponding input/output pads 44p, respectively. The conductive bumps 46 may be formed on the corresponding input/output pads 44p, respectively. In some embodiments, when the active chip 44 has a fine pitch of the conductive bumps, a thermal compression bonding may be used to bond the active chips 44 to the redistribution layer 30.

In some embodiments, a distance between two adjacent conductive bumps 46 of one of the active chips 44 may be less than or equal to a distance between two adjacent pads (e.g., the pads 20p shown in FIG. 5) of the bridge chip 20. When the distance between the conductive bumps 46 is equal to the distance between the pads 20p, the traces (e.g., the trace 32b and the trace 34b as shown in FIG. 5), the block (e.g., one of the blocks 36b shown in FIG. 5) and one of the conductive bumps 42b in the redistribution layer 30 for coupling one of the conductive bumps 46 to the corresponding pad 20p may be aligned with each other in the normal direction ND perpendicular to a top surface 12s of the carrier 12, but not limited thereto. In some embodiments, the distance between two adjacent conductive bumps 46 maybe less than the distance between two adjacent conductive pillars 16.

One of the active chips 44 may include, for example, a power management integrated circuit (PMIC), a micro-electro-mechanical-system (MEMS) chip, an application-specific integrated circuit (ASIC), a dynamic random access memory (DRAM) chip, a static random access memory (SRAM) chip, a high bandwidth memory (HBM) chip, a system on chip (SoC), a high performance computing (HPC) chip or other similar active chips, but not limited thereto. One of the conductive bumps 46 may, for example, include a multi-layer structure. One of the conductive bumps 46 may, for example, include copper, nickel, tin, silver, other suitable materials, an alloy of at least two thereof, or a combination thereof, but not limited thereto.

In the embodiment of FIG. 6, the chip group CG may include homogeneous or heterogeneous active chips 44a and 44b. When the active chip 44a and the active chip 44b are heterogeneous, the active chip 44a and the active chip 44b may be, for example, a system on chip and a high-bandwidth memory chip, respectively, but not limited thereto. For example, one chip group CG may include one active chip 44a and four active chips 44b, but not limited thereto. As mentioned herein, the active chip 44 may refer to a chip including an active element, in which the active element may include a transistor, a diode, an integrated circuit, an optoelectronic element, or other suitable elements with gain, but not limited thereto. In some embodiments, when the bridge chip 20 includes the active elements, the active elements in the bridge chip 20 and the active elements in the active chip 44 may be fabricated from different semiconductor process technology nodes, for example, a density of the active elements in the bridge chip 20 may be less than a density of the active elements in the active chip 44, but not limited thereto.

In some embodiments, since the redistribution layer 30 may be formed before the active chips 44 is disposed, an automated optical inspection (AOI) and/or an open/short test (O/S test) may be optionally performed on the redistribution layer 30 before the active chips 44 are disposed to ensure the quality of the redistribution layer 30, so that chip loss or waste caused by defect of the redistribution layer 30 may be avoided. In some embodiments, the automated optical inspection and/or the open/short test may be performed after the redistribution layer 30 is completed or may be repeated multiple times during the step of forming the redistribution layer 30.

In some embodiments, as shown in FIG. 6, after the active chips 44 are disposed on the redistribution layer 30, an underfill layer 48 may be optionally filled between the active chips 44 and the redistribution layer 30 to strengthen the bonding between the active chips 44 and the redistribution layer 30, thereby reducing breaks between the conductive bumps 42a and the conductive bumps 46 and between the conductive bumps 42b and the conductive bumps 46. The underfill layer 48 may include, for example, capillary underfill (CUF) or other suitable filling materials, but not limited thereto. The underfill layer 48 maybe formed by, for example, a dispensing process, but not limited thereto.

As shown in FIG. 7, after the active chips 44 are disposed, an encapsulant 50 may be formed on the redistribution layer 30, and the encapsulant 50 may surround the active chips 44 for protecting the active chips 44. Specifically, the encapsulant 50 may be formed between the active chips 44 and on back surfaces of the active chips 44, for example, through a molding process. The encapsulant 50 may include, for example, a molding compound or other suitable encapsulating material, but not limited thereto. A Young's modulus of the encapsulant 50 may be greater than a Young's modulus of the photosensitive encapsulation layer 28.

In the embodiment shown in FIG. 7, a thinning process may be optionally performed on the encapsulant 50 to remove a part of the encapsulant 50 located on the active chips 44, so as to expose the back surfaces of the active chips 44, thereby facilitating heat dissipation of the active chips 44. The thinning process may include, for example, a chemical mechanical polishing (CMP) process, a mechanical grinding process, an etching process or other suitable processes, but not limited thereto.

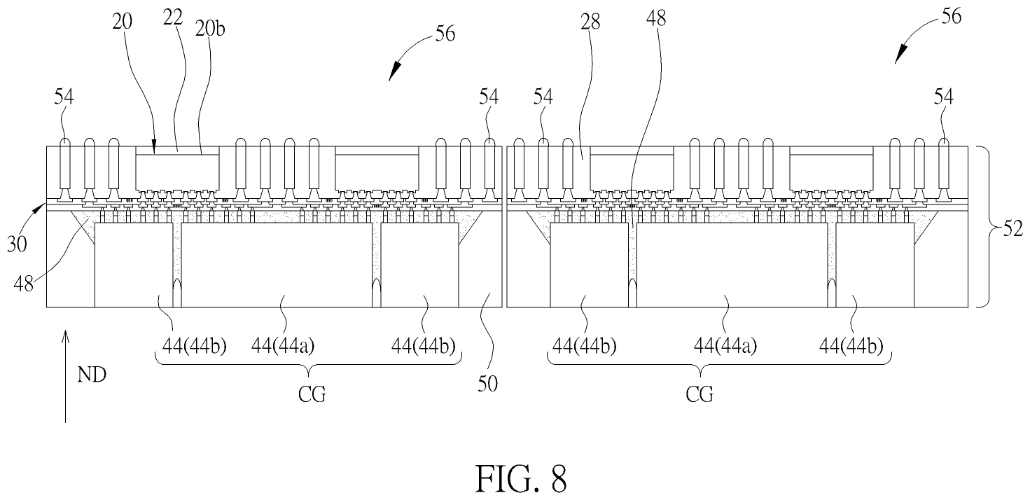

As shown in FIG. 8, after the encapsulant 50 is formed, the carrier 12 maybe removed from the conductive pillars 16, the adhesive layer 22 and the photosensitive encapsulation layer 28 to expose surfaces of the conductive pillars 16, the adhesive layer 22 and the photosensitive encapsulation layer 28 opposite to the redistribution layer 30. The method of removing the carrier 12 may include, for example, irradiating the release layer 14 with light to reduce the adhesion of the release layer 14, thereby removing the carrier 12, but not limited thereto. Then, a semi-finished structure 52 including the encapsulant 50, the active chips 44, the redistribution layer 30, the conductive pillars 16, the photosensitive encapsulation layer 28 and the bridge chip 20 may be turned upside down, so that the back surface 20b of the bridge chip 20 faces upward, and the back surfaces of the active chips 44 face downward. Subsequently, a conductive terminal 54 is formed on each of the conductive pillars 16. The conductive terminals 54 may be formed, for example, by electroplating, deposition, ball mounting, reflow, and/or other suitable processes. The conductive terminal 54 may include, for example, a solder ball, a conductive bump, or other suitable conductive terminals. The solder ball may include tin ball, for example. The conductive bump may, for example, include a multi-layer structure. The conductive bump may include, for example, copper, nickel, tin, silver, other suitable materials, an alloy of at least two thereof, or a combination thereof, but not limited thereto.

As shown in FIG. 8, a singulation process may be performed on the semi-finished structure 52 to form at least one package structure 56. In the embodiment of FIG. 8, the semi-finished structure 52 may include at least two chip groups CG, so the singulation process may separate different chip groups CG from each other and separate bridge chips 20 and the conductive pillars 16 corresponding to different chip groups CG from each other to format least two package structures 56. The singulation process may, for example, include a cutting process or other suitable processes. In some embodiments, order of the step of forming the conductive terminals 54 and the step of performing the singulation process may be interchanged with each other.

As shown in FIG. 9, after the conductive terminals 54 are formed, the package structure 56 may be turned upside down, and the conductive terminals 54 of the package structure 56 may be disposed on a substrate 58. The conductive pillars 16 of the package structure 56 may be bonded and coupled to the substrate 58 through the conductive terminals 54. Then, an underfill layer 60 may be formed between the photosensitive encapsulation layer 28 of the packaging structure 56 and the substrate 58 to form a package device 1. The substrate 58 may include, for example, a package substrate, a circuit board, or other suitable substrate. The package structure 56 may be bonded and coupled to the substrate 58 through the conductive terminals 54. The underfill layer 60 may extend to sidewalls of the photosensitive encapsulation layer 28 and the encapsulant 50 of the package structure 56, thereby strengthening the bonding between the package structure 56 and the substrate 58. The material and forming method of the underfill layer 60 may be, for example, the same as or similar to those of the underfill layer 48 and will not be detailed redundantly.

In some embodiments, a stiffener 62 may be disposed on the substrate 58, and the stiffener 62 may, for example, surround the package structure 56 and be spaced apart from the underfill layer 60. The stiffener 62 may, for example, include metal. In some embodiments, solder balls 64 may be optionally disposed under the substrate 58 to facilitate coupling and bonding of the package device 1 with other elements, but not limited thereto.

In the package device 1 shown in FIG. 9, since the trace pitch of the bridge chip 20 may be less than the trace pitch of the redistribution layer 30, the interconnection density between the active chips 44 may be improved by the bridge chip 20 coupled to different active chips 44. Accordingly, signal transmission path or time between the active chips 44 maybe decreased, thereby improving signal transmission efficiency. In this case, the trace pitch of the redistribution layer 30 does not need to reach a fine pitch, so as to simplify the process complexity and reduce the manufacturing cost. In addition, the number of layers of the redistribution layer 30 may be reduced by the bridge chip 20 with less trace pitch, thereby reducing the warpage of the package structure 56 and increasing bonding yield of the package structure 56 to the pads of the substrate 58.

Furthermore, since the adhesive layer 22 is disposed on the back surface 20b of the bridge chip 20, when the package structure 56 is disposed on the substrate 58, the adhesive layer 22 may protect the bridge chip 20 and reduce crack or disconnection in the bridge chip 20. Through the protection of the adhesive layer 22, the thickness of the bridge chip 20 in the normal direction (e.g., the normal direction ND perpendicular to a top surface of the substrate 58) may be further thinned without crack or disconnection, thereby reducing overall thickness of the package device 1 in the normal direction ND. In this case, the height of the conductive pillar 16 (e.g., the height H1 shown in FIG. 2) may be further decreased, thereby reducing the manufacturing time and cost. In addition, the pitch of the conductive pillars 16 may be reduced to provide higher signal output density and/or reduce a size of the package device 1.

It should be noted that, in the package device 1, since the redistribution layer 30 is disposed between the active chips 44 and the conductive pillars 16 and between the active chips 44 and the bridge chip 20, the active chips 44 may be coupled to the conductive pillars and the pads (e.g., the pads 20p shown in FIG. 5) of the bridge chip 20 with different pitches through the redistribution layer 30. In addition, the active chips 44 may be coupled to the substrate 58 through the redistribution layer 30 and the conductive pillars 16, and as compared with being coupled to the substrate 58 through a silicon interposer, the manufacturing cost of the conductive pillars 16 may be significantly lower than that of the silicon interposer. Therefore, the manufacturing cost of the package device 1 may be effectively reduced.

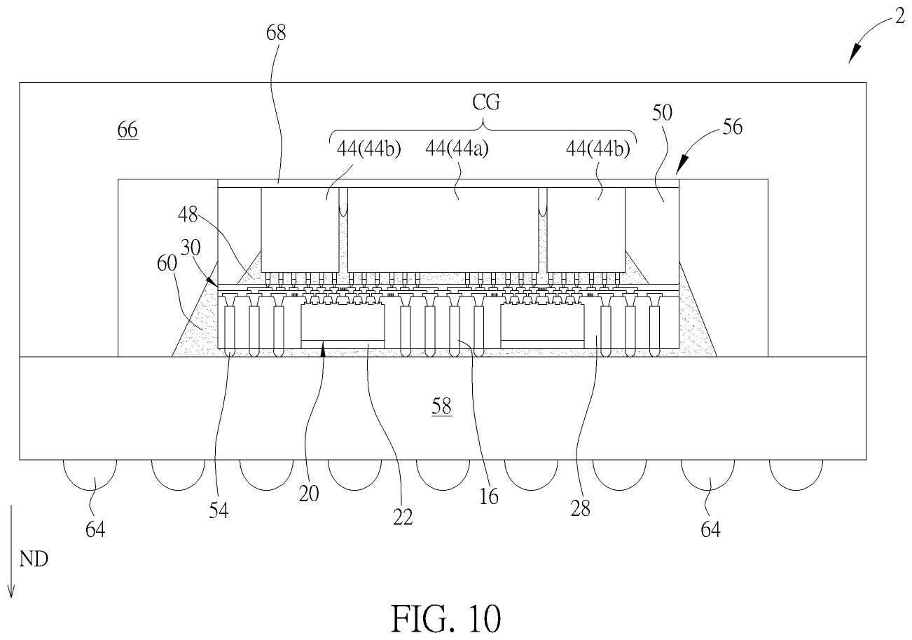

FIG. 10 schematically illustrates a cross-sectional view of a package device according to another embodiment of the present invention. As shown in FIG. 10, the package device 2 of this embodiment differs from the package device 1 shown in FIG. 9 in that the package device 2 may further include a metal cover 66 instead of the stiffener 62 in FIG. 9, and the metal cover 66 is disposed on the package structure 56 and the substrate 58. The metal cover 66 may, for example, cover and surround the package structure 56 to protect the package structure 56. The metal cover 66 may be, for example, an integrally formed structure, but not limited thereto. In some embodiments, the package device 2 may optionally further include a thermal grease 68 disposed on the back surfaces of the active chips 44. The thermal grease 68 may, for example, directly contact the active chips 44 and the metal cover 66 to facilitate heat dissipation of the active chips 44. The thermal grease 68 may be coated on the back surfaces of the active chips 44, for example, before disposing the metal cover 66, but not limited thereto.

In summary, in the package device of the present invention, the bridge chip that coupled to different active chips may improve the interconnection density between the active chips, thereby increasing the signal transmission efficiency. In addition, since the adhesive layer may be disposed on the back surface of the bridge chip, when the bridge chip is disposed on the substrate, the adhesive layer may protect the bridge chip to reduce crack or disconnection of the bridge chip. In addition, the redistribution layer may be disposed between the active chips and the conductive pillars and between the active chips and the bridge chip, so that the active chips may be coupled to the conductive pillars and the pads of the bridge chip with different pitches through the redistribution layer and may be coupled to the substrate through the conductive pillars, thereby reducing the manufacturing cost of the package device.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A package device, comprising:
a substrate;
a plurality of conductive pillars disposed on the substrate side by side;
at least one bridge chip disposed on the substrate;
a photosensitive encapsulation layer surrounding the bridge chip and the conductive pillars, wherein a distance between a top surface of the bridge chip and a top surface of the photosensitive encapsulation layer is less than a distance between a top surface of one of the conductive pillars and the top surface of the photosensitive encapsulation layer;
a redistribution layer disposed on the photosensitive encapsulation layer;
at least two active chips disposed on the redistribution layer, wherein the bridge chip is coupled between the active chips; and
an encapsulant disposed on the redistribution layer, and the encapsulant surrounding the active chips.

2. The package device as claimed in claim 1, further comprising an adhesive layer disposed between the bridge chip and the substrate.

3. The package device as claimed in claim 1, wherein the photosensitive encapsulation layer has a plurality of first through holes and a plurality of second through holes, one of the first through holes exposes one of the conductive pillars, the bridge chip has a plurality of pads, and one of the second through holes exposes one of the pads.

4. The package device as claimed in claim 3, wherein a width of one of the first through holes is greater than a width of one of the second through holes.

5. The package device as claimed in claim 3, wherein a depth of one of the first through holes is greater than a depth of one of the second through holes.

6. The package device as claimed in claim 1, wherein the photosensitive encapsulation layer is disposed between the bridge chip and the redistribution layer.

7. The package device as claimed in claim 1, wherein the bridge chip has no bump.

8. The package device as claimed in claim 1, wherein a Young's modulus of the encapsulant is greater than a Young's modulus of the photosensitive encapsulation layer.

9. The package device as claimed in claim 1, wherein the redistribution layer is disposed between the bridge chip and the active chips.

10. The package device as claimed in claim 1, further comprising an underfill layer surrounding the photosensitive layer and being disposed between the photosensitive layer and the substrate.

11. A manufacturing method of a package device, comprising:
forming a plurality of conductive pillars and disposing at least one bridge chip on a carrier;
forming a photosensitive encapsulation layer on the conductive pillars and the bridge chip, wherein the photosensitive encapsulation layer surrounds the bridge chip and the conductive pillars, and a distance between a top surface of the bridge chip and a top surface of the photosensitive encapsulation layer is less than a distance between a top surface of one of the conductive pillars and the top surface of the photosensitive encapsulation layer;
forming a redistribution layer on the photosensitive encapsulation layer;
disposing at least two active chips on the redistribution layer;
forming an encapsulant on the redistribution layer, wherein the encapsulant surrounds the active chips; and
removing the carrier.

12. The manufacturing method of the package device as claimed in claim 11, wherein disposing the bridge chip comprises bonding the bridge chip to the carrier by an adhesive layer.

13. The manufacturing method of the package device as claimed in claim 11, wherein forming the photosensitive encapsulation layer comprises forming a plurality of first through holes and a plurality of second through holes in the photosensitive encapsulation layer, one of the first through holes exposes one of the conductive pillars, the bridge chip has a plurality of pads, and one of the second through holes exposes one of the pads.

14. The manufacturing method of the package device as claimed in claim 11, wherein the photosensitive encapsulation layer is disposed between the bridge chip and the redistribution layer.

15. The manufacturing method of the package device as claimed in claim 11, wherein the bridge chip has a plurality of pads, and the redistribution layer directly contacts the pads.

16. The manufacturing method of the package device as claimed in claim 11, wherein a Young's modulus of the photosensitive encapsulation layer is less than a Young's modulus of the encapsulant.

17. The manufacturing method of the package device as claimed in claim 11, further comprising performing a thinning process on the encapsulant to expose back surfaces of the active chips.

18. The manufacturing method of the package device as claimed in claim 11, wherein between forming the redistribution layer and disposing the active chips, the manufacturing method further comprises performing an automated optical inspection on the redistribution layer.

19. The manufacturing method of the package device as claimed in claim 11, further comprising forming a plurality of conductive terminals on surfaces of the conductive pillars opposite to the redistribution layer.

20. The manufacturing method of the package device as claimed in claim 19, further comprising:
disposing the conductive terminals on a substrate; and
forming an underfill layer between the photosensitive encapsulation layer and the substrate.
